(19) United States
(12) Patent Application Publication
(10) Pub. No.: US 2026/0299018 A1
(43) Pub. Date: Oct. 1, 2026

(54) TEST HANDLER FOR ELECTRONIC COMPONENT

(71) Applicant: MIRAE Corporation, Cheonan-si (KR)

(72) Inventors: KYUNG TAE KIM, Cheonan-si (KR); UNG HYUN YOO, Cheonan-si (KR); KUK HYUNG LEE, Cheonan-si (KR)

(21) Appl. No.: 19/263,563

(22) Filed: Jul. 9, 2025

(30) Foreign Application Priority Data
Mar. 26, 2025 (KR) 10-2025-0038917
May 28, 2025 (KR) 10-2025-0069534

(51) Int. Cl. G01R 31/28

(52) U.S. Cl. CPC G01R 31/2893

(57) ABSTRACT

Proposed is a test handler for electronic components, which includes a first sorting part configured to perform a loading process of loading electronic components to be tested onto a first test tray, and an unloading process of unloading tested electronic components from the first test tray, a test part configured to perform a testing process of connecting the electronic components stored in the first test tray to test equipment, and a moving part configured to move the first test tray, wherein the moving part reciprocates the first test tray between a first waiting position and a test position.

### CROSS REFERENCE TO RELATED APPLICATION

The present application claims priority to Korean Patent Application No. 10-2025-0038917, filed Mar. 26, 2025 and Korean Patent Application No. 10-2025-0069534, filed May 28, 2025, the entire contents of which are incorporated herein for all purposes by this reference.

### BACKGROUND OF THE INVENTION

### Field of the Invention

The present disclosure relates to a test handler for electronic components configured to test electronic components and classify the electronic components by grade.

### Description of the Related Art

Memory semiconductor devices, non-memory semiconductor devices, and CPUs (Central Processing Units) (hereinafter referred to as “electronic components”) are manufactured through various processes. For example, electronic components undergo various processes, including a testing process using handler equipment such as test handlers, during which the electronic components are classified by grade.

The test handler performs a loading process, a testing process, and an unloading process for the electronic components. The loading process refers to a process in which the test handler loads the electronic components from a user tray onto a test tray. The testing process refers to a process in which the test handler connects the electronic components stored in the test tray to test equipment. The test equipment performs predetermined tests on the electronic components. The unloading process refers to a process in which the test handler unloads the electronic components from the test tray onto the user tray. In this case, the test handler may classify the electronic components by grade according to the test results.

Recently, as the need for miniaturization of electronic components has emerged, the development of electronic components referred to as microchips has been actively pursued. For example, the development of electronic components such as High Bandwidth Memory (HBM), Double Data Rate (DDR), Graphics Double Data Rate (GDDR), and Low Power Double Data Rate (LPDDR) has been actively carried out. Accordingly, the test handler is configured to perform the loading process, the testing process, and the unloading process even for such miniaturized electronic components.

FIG. 1 is a schematic plan view of a test handler according to a prior art.

Referring to FIG. 1, a test handler 1 according to the prior art sequentially moves a test tray 10 to a loading position 20, a first chamber part 5, a test chamber 4, a second chamber part 6, and an unloading position 30, performing a loading process, a testing process, and an unloading process, and then moves the test tray 10 back to the loading position 20. That is, the test handler 1 according to the prior art circulates the test tray 10 through the loading position 20, the first chamber part 5, the test chamber 4, the second chamber part 6, and the unloading position 30.

Here, the test handler 1 according to the prior art generates a considerable amount of dust during the circulation of the test tray 10, and the dust poses a risk of contaminating electronic components stored in the test tray 10. In addition, as the electronic components are contaminated by the dust, the test handler 1 according to the prior art suffers from reduced accuracy of test results, which in turn leads to decrease in the accuracy of classification by grade based on the test results.

### SUMMARY OF THE INVENTION

Accordingly, the present disclosure has been made keeping in mind the above problems occurring in the related art, and the present disclosure is intended to provide a test handler for electronic components that can improve the accuracy of test results and the accuracy of classification by grade according to the test results.

To solve the above-described problems, a test handler of the present disclosure may include the following components.

The test handler of the present disclosure may include: a first sorting part configured to perform a loading process of loading electronic components to be tested onto a first test tray, and an unloading process of unloading tested electronic components from the first test tray; a test part configured to perform a testing process of connecting the electronic components stored in the first test tray to test equipment; and a moving part configured to move the first test tray. The moving part may reciprocate the first test tray between a first waiting position and a test position.

According to the present disclosure, the following effects may be achieved.

The test handler of the present disclosure may reduce dust generated during the movement of a test tray by reducing the moving distance of the test tray. Therefore, the test handler of the present disclosure may reduce the contamination of electronic components due to dust, thereby improving the accuracy of test results.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic plan view of a test handler for electronic components according to a prior art;

FIG. 2 is a schematic block diagram of a test handler for electronic components according to the present disclosure;

FIG. 3 is a schematic plan view of the test handler for electronic components according to the present disclosure;

FIGS. 4 to 7 are schematic plan views of the operation process of a test tray in the test handler for electronic components according to the present disclosure;

FIG. 8 is a schematic block diagram of a test handler for electronic components according to a modified embodiment of the present disclosure; and

FIG. 9 is a schematic plan view of the test handler for electronic components according to the modified embodiment of the present disclosure.

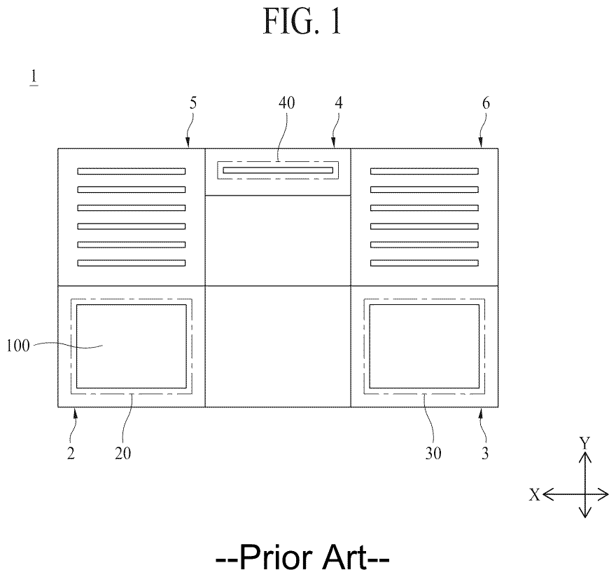

### DETAILED DESCRIPTION OF THE INVENTION

Hereinafter, an embodiment of a test handler for electronic components according to the present disclosure is described in detail with reference to the attached drawings.

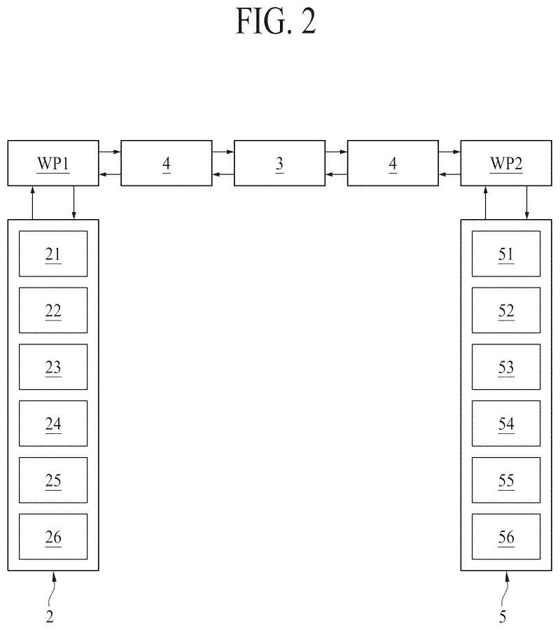

Referring to FIG. 2, a test handler 1 for electronic components according to the present disclosure is configured to test electronic components such as memory semiconductor devices, non-memory semiconductor devices, and central processing units (CPUs), and to classify the electronic components by grade according to the test results. The test handler 1 for electronic components according to the present disclosure performs a loading process, a testing process, and an unloading process for electronic components. The loading process is to load electronic components from a user tray to a test tray 10. The testing process is to connect the electronic components stored in the test tray 10 to test equipment (not shown). The unloading process is to unload the electronic components from the test tray 10 to the user tray. The unloading process may be performed by unloading the electronic components to the user tray after classifying the electronic components by grade according to the test results from the testing process. Meanwhile, referring to FIG. 2, the test handler 1 for electronic components according to the present disclosure may include a plurality of test trays 10. In this case, the test tray 10 may be divided into a first test tray 11 and a second test tray 12. The first test tray 11 and the second test tray 12 may include a plurality of first test trays 11 and a plurality of second test trays 12, respectively. In this case, the first test trays 11 and the second test trays 12 may be arranged side by side.

The test handler 1 for electronic components according to the present disclosure may include a first sorting part 2, a test part 3, a moving part 4, and a second sorting part 5.

### First Sorting Part 2

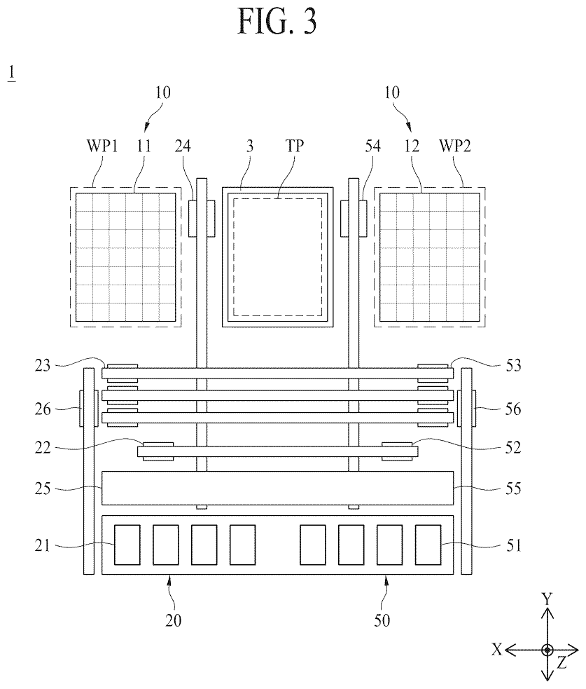

Referring to FIGS. 2 and 3, the first sorting part 2 performs the loading process. The first sorting part 2 may perform the loading process by loading electronic components to be tested onto the first test tray 11. The first sorting part 2 may load the electronic components to be tested onto the first test tray 11 located at a first waiting position WP1. The first sorting part 2 may perform the loading process for the first test tray 11 arranged in a horizontal state.

In addition, the first sorting part 2 performs the unloading process. The first sorting part 2 may perform the unloading process by unloading tested electronic components from the first test tray 11. The first sorting part 2 may unload the tested electronic components from the first test tray 11 located at the first waiting position WP1. In this way, the test handler 1 for electronic components according to the present disclosure may perform the loading and unloading processes for the first test tray 11 through the first sorting part 2.

Referring to FIGS. 2 and 3, the first sorting part 2 may include a first sorting storage part 21, a first-1 sorting picker 22, a first moving buffer 23, and a first-2 sorting picker 24 so as to perform the loading process and the unloading process.

The first sorting storage part 21 may store user trays. The user trays may store a plurality of electronic components. The first sorting storage part 21 may store the user trays containing electronic components to be tested by stacking the user trays, may store user trays containing tested electronic components by stacking the user trays, and may store empty user trays by stacking the user trays. The first sorting storage part 21 may also store wafer rings or reels in place of the user trays.

When performing the loading process, the first-1 sorting picker 22 may pick up the electronic components from the first sorting storage part 21 and place the electronic components onto the first moving buffer 23. When performing the unloading process, the first-1 sorting picker 22 may pick up the electronic components from the first moving buffer 23 and place the electronic components onto the first sorting storage part 21. The first-1 sorting picker 22 may be movable in a first axial direction (an X-axis direction) and a second axial direction (a Y-axis direction). The first axial direction (the X-axis direction) and the second axial direction (the Y-axis direction) are axial directions orthogonal to each other. The first-1 sorting picker 22 may move up and down along a vertical direction (a Z-axis direction). The vertical direction (the Z-axis direction) is an axial direction perpendicular to both the first axial direction (the X-axis direction) and the second axial direction (the Y-axis direction).

The first moving buffer 23 may be disposed between the first sorting storage part 21 and the first waiting position WP1. The first moving buffer 23 may be movable in the first axial direction (the X-axis direction). The first moving buffer 23 may store a plurality of electronic components. Spacing between the electronic components stored in the first moving buffer 23 may correspond to spacing between the electronic components stored in the first test tray 11. A plurality of first moving buffers 23 may be arranged along the second axial direction (the Y-axis direction).

When performing the loading process, the first-2 sorting picker 24 may pick up electronic components from the first moving buffer 23 and place the electronic components onto the first test tray 11 located at the first waiting position WP1. In this case, the first-2 sorting picker 24 may pick up a plurality of electronic components simultaneously from the first moving buffer 23. When performing the unloading process, the first-2 sorting picker 24 may pick up the electronic components from the first test tray 11 located at the first waiting position WP1 and place the electronic components onto the first moving buffer 23. In this case, the first-2 sorting picker 24 may pick up the plurality of electronic components simultaneously from the first test tray 11. The first-2 sorting picker 24 may move in the second axial direction (the Y-axis direction). The first-2 sorting picker 24 may also move in both the first axial direction (the X-axis direction) and the second axial direction (the Y-axis direction). The first-2 sorting picker 24 may move up and down along the vertical direction (the Z-axis direction).

Referring to FIGS. 2 and 3, the first sorting part 2 may include a first fixed buffer 25 and a first-3 sorting picker 26.

The first fixed buffer 25 may be disposed between the first sorting storage part 21 and the first moving buffer 23. When the first fixed buffer 25 is provided, the first-1 sorting picker 22 may perform the loading process by picking up electronic components from the first sorting storage part 21 and placing the electronic components onto the first fixed buffer 25. The first-1 sorting picker 22 may perform the unloading process by picking up the electronic components from the first fixed buffer 25 and placing the electronic components onto the first sorting storage part 21. In this case, the first-1 sorting picker 22 may also perform the unloading process by picking up electronic components from the first moving buffer 23 and placing the electronic components onto the first sorting storage part 21.

When performing the loading process, the first-3 sorting picker 26 may pick up electronic components from the first fixed buffer 25 and place the electronic components onto the first moving buffer 23. When performing the unloading process, the first-3 sorting picker 26 may pick up electronic components from the first moving buffer 23 and place the electronic components onto the first fixed buffer 25. The first-3 sorting picker 26 may move in the second axial direction (the Y-axis direction). The first-3 sorting picker 26 may move in the first axial direction (the X-axis direction) and the second axial direction (the Y-axis direction). The first-3 sorting picker 26 may move up and down along the vertical direction (the Z-axis direction).

### Test Part 3

Referring to FIGS. 2 and 3, the test part 3 performs the testing process. The test part 3 may perform the testing process by connecting electronic components stored in the test tray 10 to the test equipment (not shown). The test part 3 may alternately perform a testing process for electronic components stored in the first test tray 11 and a testing process for electronic components stored in the second test tray 12. Meanwhile, the test part 3 may include a test position TP. At the test position TP, the testing process may be performed.

### Transfer Part 4

Referring to FIGS. 2 and 3, the moving part 4 moves the test tray. The moving part 4 may move the first test tray 11 from the first waiting position WP1 to the test position TP. The first waiting position WP1 and the test position TP may be arranged to be spaced apart from each other along the first axial direction. In addition, the moving part 4 may move the second test tray 12 from a second waiting position WP2 to the test position TP. The second waiting position WP2 and the test position TP may be disposed to be spaced apart from each other along the first axial direction. The test position TP may be arranged between the first waiting position WP1 and the second waiting position WP2 along the first axial direction. The moving part 4 may be implemented as a rail. In this case, the test tray may move between the first waiting position WP1 and the test position TP along the rail. In addition, the test tray may move between the second waiting position WP2 and the test position TP. Meanwhile, a driving device (not shown) that provides driving force may be connected to the moving part 4.

Referring to FIGS. 2 and 3, the moving part 4 may reciprocate the first test tray 11 between the first waiting position WP1 and the test position TP. Accordingly, the test handler 1 for electronic components according to the present disclosure may reduce dust generated during the movement of the first test tray 11 by reducing the movement distance of the first test tray 11. Accordingly, the test handler 1 for electronic components according to the present disclosure may reduce contamination of electronic components caused by dust, thereby improving the accuracy of test results. In this way, the test handler 1 for electronic components according to the present disclosure may discharge the first test tray 11 on which the testing process has been completed in the direction in which the first test tray 11 was transferred for the testing process.

When the first test tray 11 which is empty is located at the first waiting position WP1, the first sorting part 2 may perform the loading process for the first test tray 11. When the test position TP is empty after the loading process for the first test tray 11 is completed, the first test tray 11 may be moved to the test position TP by the moving part 4. In addition, the testing process may be performed on electronic components stored in the first test tray 11. After the testing process is completed, when the first test tray 11 is moved to the first waiting position WP1, the first sorting part 2 may perform the unloading process for the first test tray 11.

As described above, the test handler 1 for electronic components according to the present disclosure is configured to perform the loading process, the testing process, and the unloading process while moving the first test tray 11 only between the first waiting position WP1 and the test position TP. Accordingly, the test handler 1 for electronic components according to the present disclosure may reduce dust generated during the movement of the test tray by reducing the movement distance of the test tray. Accordingly, the test handler 1 for electronic components according to the present disclosure may reduce contamination of electronic components caused by dust, thereby improving the accuracy of test results. Meanwhile, one test tray may be located at each of the first waiting position WP1 and the test position TP. Two or more test trays may be located at each of the first waiting position WP1 and the test position TP. In this case, the testing process may be performed on electronic components stored in the plurality of test trays at the test position TP.

### Second Sorting Part 5

Referring to FIGS. 2 and 3, the second sorting part 5 performs the loading process. The second sorting part 5 may perform the loading process by loading electronic components to be tested onto the second test tray 12. The second sorting part 5 may load the electronic components to be tested onto the second test tray 12 located at the second waiting position WP2. The second sorting part 5 may perform the loading process for the second test tray 12 arranged in a horizontal state.

In addition, the second sorting part 5 performs the unloading process. The second sorting part 5 may perform the unloading process by unloading tested electronic components from the second test tray 12. The second sorting part 5 may unload the tested electronic components from the second test tray 12 located at the second waiting position WP2. The test handler 1 for electronic components according to the present disclosure may perform the loading process and the unloading process for the second test tray 12 through the second sorting part 5.

Meanwhile, the second sorting part 5 may be disposed to be spaced apart from the first sorting part 2 along the first axial direction. The second sorting part 5 and the first sorting part 2 may be arranged symmetrically with respect to the second axial direction. That is, the second sorting part 5 and the first sorting part 2 may be arranged to face each other along the first axial direction.

Referring to FIGS. 2 and 3, the second sorting part 5 may include a second sorting storage part 51, a second-1 sorting picker 52, a second moving buffer 53, and a second-2 sorting picker 54 in order to perform the loading process and the unloading process.

The second sorting storage part 51 may store user trays. The user trays may store a plurality of electronic components. The second sorting storage part 51 may store user trays containing electronic components to be tested by stacking the user trays, may store user trays containing tested electronic components by stacking the user trays, and may store empty user trays by stacking the empty user trays. The second sorting storage part 51 may store wafer rings or reels in place of user trays.

When performing the loading process, the second-1 sorting picker 52 may pick up electronic components from the second sorting storage part 51 and place the electronic components onto the second moving buffer 53. When performing the unloading process, the second-1 sorting picker 52 may pick up the electronic components from the second moving buffer 53 and place the electronic components onto the second sorting storage part 51. The second-1 sorting picker 52 may move in the first axial direction (the X-axis direction) and the second axial direction (the Y-axis direction). The second-1 sorting picker 52 may move up and down along the vertical direction (the Z-axis direction).

The second moving buffer 53 may be disposed between the second sorting storage part 51 and the second waiting position WP2. The second moving buffer 53 may move in the first axial direction (the X-axis direction). The second moving buffer 53 may store a plurality of electronic components. Spacing between the electronic components stored in the second moving buffer 53 may correspond to spacing between the electronic components stored in the second test tray 12. A plurality of second moving buffers 53 may be arranged along the second axial direction (the Y-axis direction).

When performing the loading process, the second-2 sorting picker 54 may pick up electronic components from the second moving buffer 53 and place the electronic components onto the second test tray 12 located at the second waiting position WP2. In this case, the second-2 sorting picker 54 may simultaneously pick up a plurality of electronic components from the second moving buffer 53. When performing the unloading process, the second-2 sorting picker 54 may pick up the electronic components from the second test tray 12 located at the second waiting position WP2 and place the electronic components onto the second moving buffer 53. In this case, the second-2 sorting picker 54 may simultaneously pick up a plurality of electronic components from the second test tray 12. The second-2 sorting picker 54 may move in the second axial direction (the Y-axis direction). The second-2 sorting picker 54 may also move in both the first axial direction (the X-axis direction) and the second axial direction (the Y-axis direction). The second-2 sorting picker 54 may move up and down along the vertical direction (the Z-axis direction).

The second sorting part 5 may include a second fixed buffer 55, and a second-3 sorting picker 56.

The second fixed buffer 55 may be arranged between the second sorting storage part 51 and the second moving buffer 53. When the second fixed buffer 55 is provided, the second-1 sorting picker 52 may perform the loading process by picking up electronic components from the second sorting storage part 51 and placing the electronic components onto the second fixed buffer 55. The second-1 sorting picker 52 may perform the unloading process by picking up the electronic components from the second fixed buffer 55 and placing the electronic components onto the second sorting storage part 51. In this case, the second-1 sorting picker 52 may perform the unloading process by picking up electronic components from the second moving buffer 53 and placing the electronic components onto the second sorting storage part 51.

When performing the loading process, the second-3 sorting picker 56 may pick up electronic components from the second fixed buffer 55 and place the electronic components onto the second moving buffer 53. When performing the unloading process, the second-3 sorting picker 56 may pick up electronic components from the second moving buffer 53 and place the electronic components onto the second fixed buffer 55. The second-3 sorting picker 56 may move in the second axial direction (the Y-axis direction). The second-3 sorting picker 56 may also move in both the first axial direction (the X-axis direction) and the second axial direction (the Y-axis direction). The second-3 sorting picker 56 may move up and down along the vertical direction (the Z-axis direction).

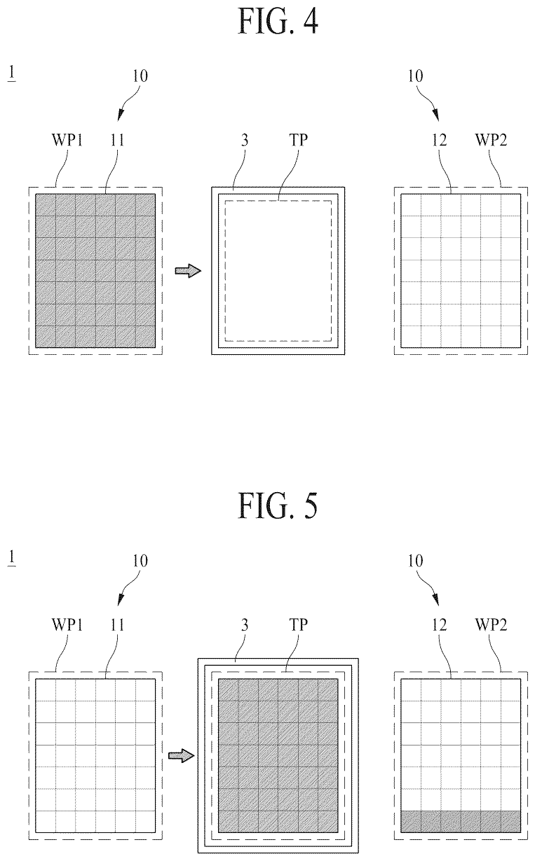

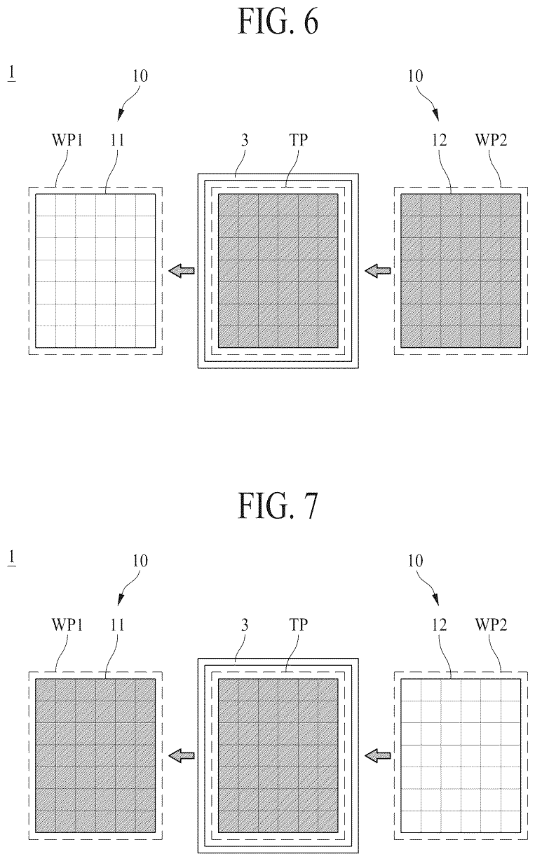

Here, referring to FIGS. 2 to 7, the operation processes of the first test tray 11 and the second test tray 12 are described in detail. Black portions on the first test tray 11 and the second test tray 12 illustrated in FIGS. 4 to 7 indicate that electronic components are loaded.

First, when the loading process for the first test tray 11 is completed by the first sorting part 2, the first test tray 11 may be moved from the first waiting position WP1 to the test position TP by the moving part 4.

Next, the testing process for the first test tray 11 may be performed by the test part 3. While the testing process for the first test tray 11 is being performed, the loading process for the second test tray 12 may be performed by the second sorting part 5. The loading process for the second test tray 12 may be completed before the testing process for the first test tray 11 is completed.

Next, when the testing process for the first test tray 11 is completed by the test part 3, the first test tray 11 may be moved from the test position TP to the first waiting position WP1 by the moving part 4. At the same time, the second test tray 12 may be moved from the second waiting position WP2 to the test position TP by the moving part 4.

Next, the testing process for the second test tray 12 may be performed by the test part 3. While the testing process for the second test tray 12 is being performed, the unloading process for the first test tray 11 may be performed by the first sorting part 2. When the unloading process for the first test tray 11 is completed, the loading process for the first test tray 11 may be performed by the first sorting part 2. In this case, before the testing process for the second test tray 12 is completed, the unloading process and the loading process for the first test tray 11 may be sequentially completed. In this way, the test handler 1 for electronic components according to the present disclosure may repeatedly perform the aforementioned operation processes.

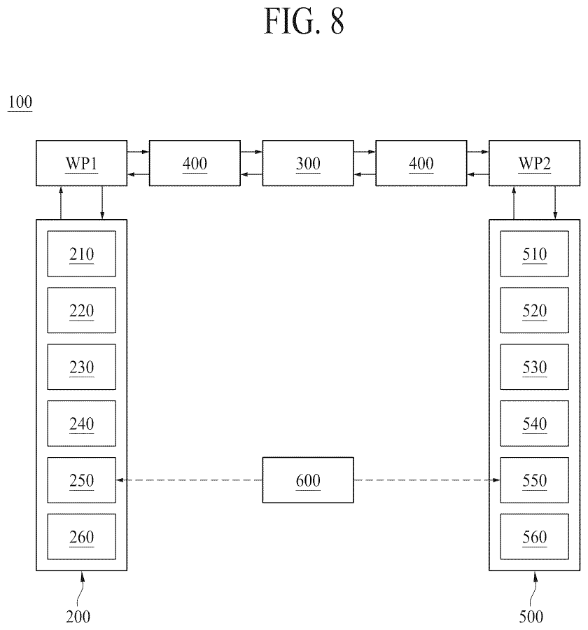

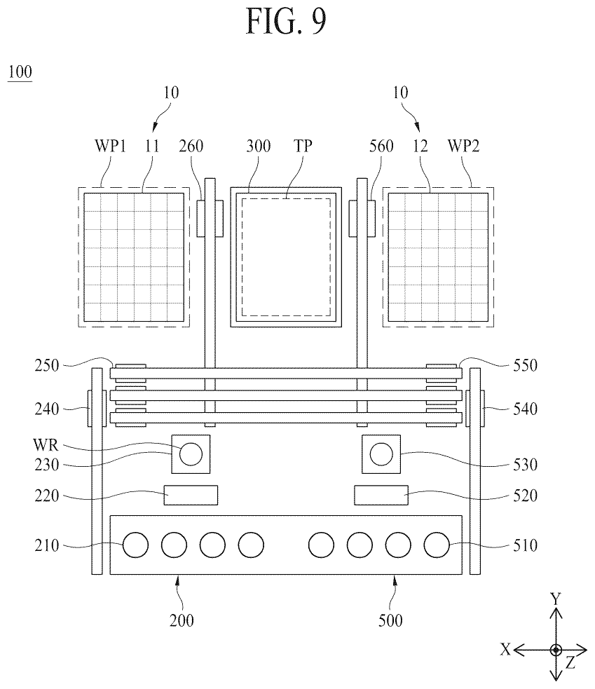

Below, referring to FIGS. 8 and 9, a modified embodiment of the test handler of the present disclosure will be described.

A test handler 100 for electronic components according to the modified embodiment of the present disclosure differs from the above-described embodiment in that the test handler includes a loading part 200 and an unloading part 500 in place of the first sorting part 2 (shown in FIG. 2), and in that the test handler loads electronic components from wafer rings WR onto a test tray 10 and unloads electronic components from the test tray 10 onto the wafer rings WR. The wafer rings WR may include a ring frame and an adhesive member (such as blue tape, not shown) disposed on the inner side of the ring frame. The ring frame may be formed as a circular ring-shaped structure with a hollow interior. Meanwhile, in the test handler 100 for electronic components according to the modified embodiment of the present disclosure, a test part 300 having the test chamber and a moving part 400 may be implemented approximately in the same manner as in the above-described embodiment. Accordingly, a detailed description of the test part 300 and the moving part 400 in the test handler 100 for electronic components according to the modified embodiment of the present disclosure will be omitted.

Referring to FIGS. 8 and 9, the loading part 200 may include a loading storage part 210, a loading robot 220, a loading table 230, a loading picker 240, a loading buffer 250, and a first sorting picker 260.

The loading storage part 210 may store the wafer rings WR. Electronic components to be tested are placed on the wafer rings WR. In this case, the electronic components may be adhered to the adhesive member provided on the wafer rings WR. The loading storage part 210 may store the wafer rings WR, on which the electronic components to be tested are placed, by stacking the wafer rings WR.

The loading robot 220 may move the wafer rings WR from the loading storage part 210 to the loading table 230. The loading robot 220 may move the wafer rings WR by holding or supporting the wafer rings WR by using a robotic arm thereof, or may move the wafer rings WR by suctioning the wafer rings WR by using a suction mechanism.

The loading table 230 may support the wafer rings WR. After the wafer rings WR are placed on the loading table 230 by the loading robot 220, the loading table 230 may increase spacing between electronic components by tensioning the adhesive member.

The loading picker 240 may pick up the electronic components from the wafer rings WR supported on the loading table 230 and place the electronic components onto the loading buffer 250. In this case, since the spacing between the electronic components is increased by the loading table 230, the loading picker 240 may pick up the electronic components sequentially. The loading picker 240 may move in the first axial direction (the X-axis direction) and the second axial direction (the Y-axis direction). The loading picker 240 may move up and down along the vertical direction (the Z-axis direction).

The loading buffer 250 may be arranged between the loading table 230 and the first waiting position WP1. The loading buffer 250 may move in the first axial direction (the X-axis direction). The loading buffer 250 may store a plurality of electronic components. Spacing between the electronic components stored in the loading buffer 250 may correspond to spacing between electronic components stored in the first test tray 11. A plurality of loading buffers 250 may be arranged along the second axial direction (the Y-axis direction).

When performing the loading process, the first sorting picker 260 may pick up electronic components from the loading buffer 250 and place the electronic components onto the first test tray 11 located at the first waiting position WP1. When performing the unloading process, the first sorting picker 260 may pick up electronic components from the first test tray 11 located at the first waiting position WP1 and place the electronic components onto an unloading buffer 550 provided in the unloading part 500. In this case, the unloading buffer 550 may be moved toward the loading part 200 and used for the unloading process for the first test tray 11. When performing the unloading process, the first sorting picker 260 may pick up electronic components from the first test tray 11 located at the first waiting position WP1 and place the electronic components onto the loading buffer 250. In this case, the loading buffer 250 may be moved toward the unloading part 500 and used for the unloading process. When all of the electronic components placed on the loading buffer 250 are unloaded by the unloading part 500, the loading buffer 250 may be moved toward the loading part 200 and be used for the loading process for the first test tray 11. The first sorting picker 260 may move in the second axial direction (the Y-axis direction). The first sorting picker 260 may also move in both the first axial direction (the X-axis direction) and the second axial direction (the Y-axis direction). The first sorting picker 260 may move up and down along the vertical direction (the Z-axis direction).

The unloading part 500 may include an unloading storage part 510, an unloading robot 520, an unloading table 530, an unloading picker 540, the unloading buffer 550, and a second sorting picker 560.

The unloading storage part 510 may store the wafer rings WR. Tested electronic components may be placed on the wafer rings WR. In this case, the electronic components may be adhered to adhesive members provided on the wafer rings WR. Each of the adhesive members may be in a non-tensioned state. The unloading storage part 510 may store the wafer rings WR, on which the tested electronic components are placed, by stacking the wafer rings WR.

The unloading robot 520 may move the wafer rings WR, on which the tested electronic components are placed, from the unloading table 530 to the unloading storage part 510. The unloading robot 520 may move the wafer rings WR by holding or supporting the wafer rings WR by using a robotic arm, or by suctioning the wafer rings WR by using a suction mechanism.

The unloading table 530 may support the wafer rings WR. In this case, each of the adhesive members provided on the wafer rings WR may be in a non-tensioned state.

The unloading picker 540 may pick up electronic components from the unloading buffer 550 and place the electronic components onto the wafer rings WR supported on the unloading table 530. When the electronic components are unloaded from the first test tray 11, stored in the loading buffer 250, and then the loading buffer 250 is moved toward the unloading part 500, the unloading picker 540 may pick up the electronic components from the loading buffer 250 and place the electronic components onto the wafer rings WR supported on the unloading table 530. The unloading picker 540 may move in the first axial direction (the X-axis direction) and the second axial direction (the Y-axis direction). The unloading picker 540 may move up and down along the vertical direction (the Z-axis direction).

The unloading buffer 550 may be arranged between the unloading table 530 and the second waiting position WP2. The unloading buffer 550 may move in the first axial direction (the X-axis direction). The unloading buffer 550 may store a plurality of electronic components. Spacing between the electronic components stored in the unloading buffer 550 may correspond to spacing between electronic components stored in the second test tray 12. A plurality of unloading buffers 550 may be arranged along the second axial direction (the Y-axis direction).

When performing the unloading process, the second sorting picker 560 may pick up electronic components from the second test tray 12 located at the second waiting position WP2 and place the electronic components onto the unloading buffer 550. When performing the loading process, the second sorting picker 560 may pick up electronic components from the unloading buffer 550 and place the electronic components onto the second test tray 12 located at the second waiting position WP2. When performing the loading process, the second sorting picker 560 may pick up electronic components from the loading buffer 250 and place the electronic components onto the second test tray 12 located at the second waiting position WP2. In this case, after the electronic components to be tested are stored in the loading buffer 250, the loading buffer 250 may be moved toward the unloading part 500 and be used for the loading process of the second test tray 12. When all of the electronic components placed on the loading buffer 250 are loaded onto the second test tray 12 by the second sorting picker 560, the loading buffer 250 may be moved toward the loading part 200 and be used for the loading process and the unloading process for the first test tray 11. The second sorting picker 560 may move in the second axial direction (the Y-axis direction). The second sorting picker 560 may also move in both the first axial direction (the X-axis direction) and the second axial direction (the Y-axis direction). The second sorting picker 560 may move up and down along the vertical direction (the Z-axis direction).

Meanwhile, among the plurality of moving buffers, the buffer used for the loading process corresponds to the loading buffer 250, and the buffer used for the unloading process corresponds to the unloading buffer 550.

In this case, some of the moving buffers may be implemented as the loading buffer 250, which is used exclusively for the loading process, and some of the moving buffers may be implemented as the unloading buffer 550, which is used exclusively for the unloading process. The loading buffer 250 may be used for the loading process for the first test tray 11 and the loading process for the second test tray 12. The unloading buffer 550 may be used for the unloading process for the first test tray 11 and the unloading process for the second test tray 12.

Alternatively, each of the moving buffers may be used for both the loading process and the unloading process. In this case, each of the moving buffers may function as the loading buffer 250 when used for the loading process and may function as the unloading buffer 550 when used for the unloading process. For example, the loading buffer 250 used for the loading process for the first test tray 11 may be used for the unloading process for the first test tray 11 or the second test tray 12. The unloading buffer 550 used for the unloading process for the second test tray 12 may be used for the loading process for the first test tray 11 or the second test tray 12. This switching between the loading buffer 250 and the unloading buffer 550 may be performed by a controller 600. When electronic components to be tested need to be moved from the loading table 230 to the loading buffer 250, the controller 600 may control an empty moving buffer among the moving buffers to function as the loading buffer 250. When tested electronic components need to be unloaded from the first test tray 11 or the second test tray 12, the controller 600 may control an empty moving buffer among the moving buffers to function as the unloading buffer 550.

The present disclosure described above is not limited to the aforementioned embodiments and the accompanying drawings, and various substitutions, modifications, and changes may be made without departing from the technical spirit of the present disclosure, which will be apparent to those skilled in the art to which the present disclosure pertains.

1. A test handler for electronic components, the test handler comprising:
a first sorting part configured to perform a loading process of loading electronic components to be tested onto a first test tray, and an unloading process of unloading tested electronic components from the first test tray;
a test part configured to perform a testing process of connecting the electronic components stored in the first test tray to test equipment; and
a moving part configured to move the first test tray,
wherein the moving part reciprocates the first test tray between a first waiting position and a test position.

2. The test handler of claim 1, wherein the moving part moves the first test tray from the first waiting position to the test position, and
the test part performs the testing process for the first test tray moved to the test position.

3. The test handler of claim 2, wherein when the testing process for the first test tray is completed, the moving part moves the first test tray from the test position to the first waiting position.

4. The test handler of claim 1, further comprising:
a second sorting part configured to perform a loading process of loading electronic components to be tested onto a second test tray, and an unloading process of unloading tested electronic components from the second test tray,
wherein while the testing process for the first test tray is being performed, the second sorting part performs the loading process for the second test tray.

5. The test handler of claim 4, wherein before the testing process for the first test tray is completed, the second sorting part completes the loading process for the second test tray.

6. The test handler of claim 2, further comprising:
a second sorting part configured to perform a loading process of loading electronic components to be tested onto a second test tray, and an unloading process of unloading tested electronic components from the second test tray,
wherein when the testing process for the first test tray is completed, the moving part moves the first test tray from the test position to the first waiting position and moves the second test tray from a second waiting position to the test position.

7. The test handler of claim 6, wherein the test part performs a testing process on the electronic components stored in the second test tray, and
while the testing process for the second test tray is being performed, the first sorting part sequentially performs the unloading process and the loading process for the first test tray.

8. The test handler of claim 7, wherein before the testing process for the second test tray is completed, the first sorting part completes the unloading process and the loading process for the first test tray.

9. The test handler of claim 2, further comprising:
a second sorting part configured to perform a loading process of loading electronic components to be tested onto a second test tray, and an unloading process of unloading tested electronic components from the second test tray,
wherein the moving part reciprocates the second test tray between a second waiting position and the test position.

10. The test handler of claim 1, wherein when the loading process for the first test tray is completed, the moving part moves the first test tray from the first waiting position to the test position, and
when the testing process for the first test tray is completed, the moving part moves the first test tray from the test position to the first waiting position.

11. A test handler for electronic components, the test handler comprising:
a loading part configured to perform a loading process of loading electronic components to be tested from a wafer ring onto a first test tray;
an unloading part configured to perform an unloading process of unloading tested electronic components from the first test tray onto the wafer ring;
a test part configured to perform a testing process of connecting the electronic components stored in the first test tray to test equipment; and
a moving part configured to move the first test tray,
wherein the moving part reciprocates the first test tray between a first waiting position and a test position.

12. The test handler of claim 11, wherein the loading part comprises:
a loading table configured to support the wafer ring;
a loading buffer arranged between the loading table and the first waiting position; and
a first sorting picker configured to move electronic components between the loading table and the loading buffer.

13. The test handler of claim 12, wherein when performing the unloading process for the first test tray, the first sorting picker picks up the electronic components from the first test tray located at the first waiting position and places the electronic components onto an unloading buffer provided in the unloading part, and
the unloading buffer is moved toward the loading part and is used for the unloading process for the first test tray.

14. The test handler of claim 12, wherein when performing the unloading process for the first test tray, the first sorting picker picks up the electronic components from the first test tray located at the first waiting position and places the electronic components onto the loading buffer, and
the loading buffer is moved toward the unloading part and is used for the unloading process of the first test tray.

15. The test handler of claim 14, wherein when all of the electronic components placed on the loading buffer are unloaded by the unloading part, the loading buffer is moved toward the loading part and is used for the loading process for the first test tray.
